(19) United States
(12) Patent Application Publication
(10) Pub. No.: US 2025/0380497 A1
(43) Pub. Date: Dec. 11, 2025

(54) SEMICONDUCTOR DEVICE AND METHOD OF FABRICATING THE SAME

(71) Applicant: SAMSUNG ELECTRONICS CO., LTD., Suwon-si (KR)

(72) Inventors: Hyunggoo LEE, Suwon-si (KR); Sungwoo KANG, Suwon-si (KR); Kyongbeom KOH, Suwon-si (KR); Gwanho KIM, Suwon-si (KR); Ki-II KIM, Suwon-si (KR); Hyonwook RA, Suwon-si (KR)

(73) Assignee: SAMSUNG ELECTRONICS CO., LTD., Suwon-si (KR)

(21) Appl. No.: 18/986,092

(22) Filed: Dec. 18, 2024

(30) Foreign Application Priority Data
Jun. 5, 2024 (KR) 10-2024-0073628

(51) Int. Cl. H10D 84/83; H01L 23/528; H10D 30/00; H10D 30/01; H10D 30/43; H10D 62/10; H10D 62/13; H10D 64/23; H10D 84/01

(52) U.S. Cl. CPC H10D 84/832; H01L 23/5286; H10D 30/43; H10D 30/503; H10D 30/506; H10D 62/102; H10D 62/121; H10D 62/151; H10D 64/256; H10D 30/014; H10D 30/0191; H10D 84/0149

(57) ABSTRACT

Provided is a semiconductor device and method of manufacturing same, the semiconductor device including: a plurality of active patterns on a substrate; a source/drain pattern on the substrate; a power rail in the substrate; a pillar pattern between the plurality of active patterns; a channel pattern on the pillar pattern; a backside conductive contact between the source/drain pattern and the power rail; and a liner pattern on the pillar pattern, wherein the liner pattern includes: a first portion that covers a top surface of a lower portion of the backside conductive contact; and a second portion that extends from the first portion and along a sidewall of the lower portion of the backside conductive contact.

### CROSS-REFERENCE TO RELATED APPLICATION

This U.S. nonprovisional application is based on and claims priority to Korean Patent Application No. 10-2024-0073628 filed on Jun. 5, 2024 in the Korean Intellectual Property Office, the disclosure of which is hereby incorporated by reference in its entirety.

### BACKGROUND

### 1. Field

The present disclosure relates to a semiconductor device and a method of fabricating the same, and more particularly, to a semiconductor device including a field effect transistor and a method of fabricating the same.

### 2. Description of Related Art

A semiconductor device may include an integrated circuit including metal oxide semiconductor field effect transistors (MOSFETs). As sizes and design rules of semiconductor devices are gradually decreased, sizes of the MOSFETs included in such devices are also increasingly scaled down. The scale down of MOSFETs may result in deterioration of the operating characteristics of the semiconductor device. Accordingly, various studies have been conducted to develop methods of fabricating semiconductor devices having superior performances while overcoming limitations caused by high integration of the semiconductor devices.

### SUMMARY

Provided is a semiconductor device with improved productivity and electrical properties and a method of fabricating the same.

According to an aspect of the disclosure, a semiconductor device includes: a plurality of active patterns on a substrate; a source/drain pattern on the substrate; a power rail in the substrate; a pillar pattern between the plurality of active patterns; a channel pattern on the pillar pattern; a backside conductive contact between the source/drain pattern and the power rail; and a liner pattern on the pillar pattern, wherein the liner pattern includes: a first portion that covers a top surface of a lower portion of the backside conductive contact; and a second portion that extends from the first portion and along a sidewall of the lower portion of the backside conductive contact.

According to an aspect of the disclosure, a semiconductor device includes: a plurality of active patterns on a substrate; a source/drain pattern on the substrate; a power rail in the substrate; a pillar pattern between the plurality of active patterns; a channel pattern on the pillar pattern; a backside conductive contact between the source/drain pattern and the power rail; and a liner pattern between the pillar pattern and a lower portion of the backside conductive contact.

According to an aspect of the disclosure, a semiconductor device includes: a plurality of active patterns on a substrate; a source/drain pattern on the substrate; a power delivery network layer on a bottom surface of the substrate; a power rail in the substrate; a pillar pattern between the plurality of active patterns; a channel pattern on the pillar pattern; a gate electrode between the plurality of semiconductor patterns; a backside conductive contact between the source/drain pattern and the power rail; and a liner pattern on the pillar pattern, wherein the liner pattern includes: a first portion that covers a top surface of a lower portion of the backside conductive contact; and a second portion that extends from the first portion and along a sidewall of the lower portion of the backside conductive contact.

The present disclosure is not limited to the features and aspects mentioned above, and other features and aspects which have not been mentioned above will be clearly understood to those skilled in the art from the following description.

### BRIEF DESCRIPTION OF DRAWINGS

The above and other aspects and features of certain embodiments of the present disclosure will be more apparent from the following description taken in conjunction with the accompanying drawings, in which:

FIG. 1 illustrates a plan view showing a semiconductor device according to one or more embodiments of the present disclosure;

FIGS. 2A and 2B illustrate cross-sectional views respectively taken along lines A-A′ and B-B′ of FIG. 1; and

FIGS. 3A, 3B, 4A, 4B, 4C, 5, 6, 7, 8, and 9 illustrate cross-sectional views showing a method of fabricating a semiconductor device according to one or more embodiments of the present disclosure.

### DETAILED DESCRIPTION

One or more embodiments of the present disclosure will now be described in detail with reference to the accompanying drawings to aid in clearly explaining the present disclosure. In the following description, like reference numerals refer to like elements throughout the specification.

In this disclosure, each of the expressions “A or B”, “at least one of A and B”, “at least one A or B”, “A, B, or C”, “at least one of A, B, and C”, and “at least one A, B, or C” may include any one of, or any possible combination of, the elements listed in a corresponding one of the expressions mentioned above.

As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

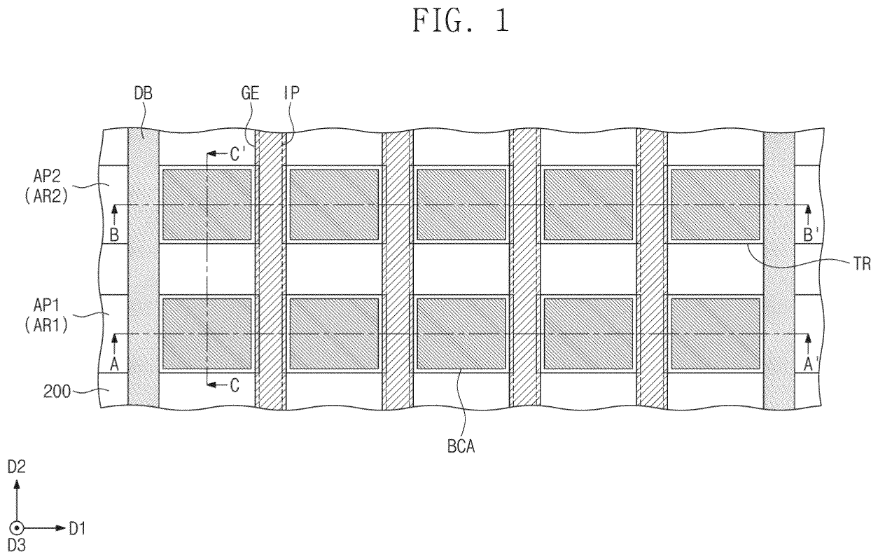

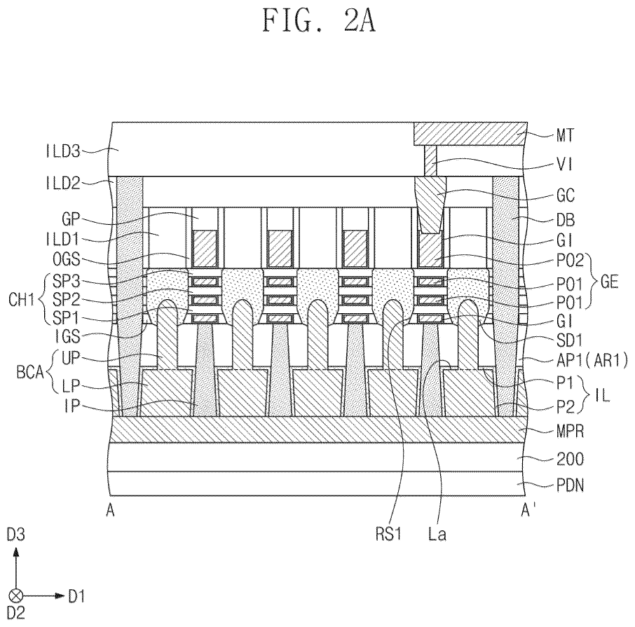

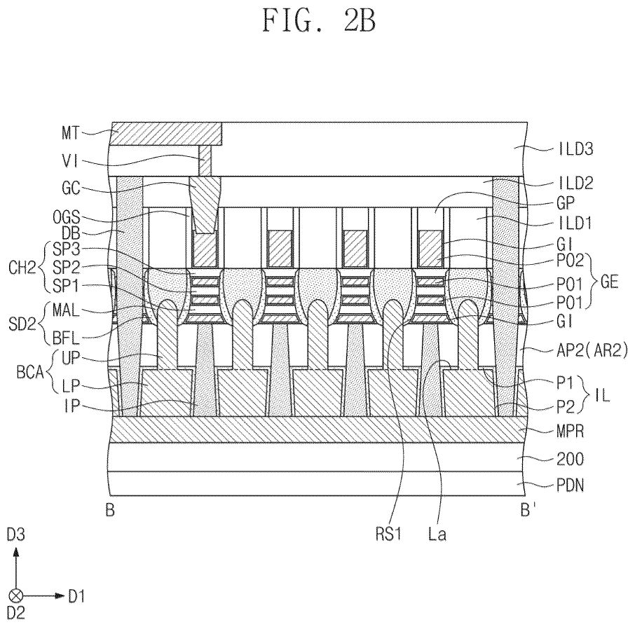

FIG. 1 illustrates a plan view showing a semiconductor device according to one or more embodiments of the present disclosure. FIGS. 2A and 2B illustrate cross-sectional views respectively taken along lines A-A′ and B-B′ of FIG. 1.

Referring to FIGS. 1, 2A, and 2B, a substrate 200 may be provided which includes a single height cell. For example, the substrate 200 may be a dielectric substrate. The substrate 200 may include at least one selected from a silicon oxide (SiO₂) layer, a silicon nitride (SiN) layer, and a silicon oxynitride (SiON) layer.

The single height cell may constitute one logic cell. In this disclosure, the logic cell may mean a logic device (e.g., AND, OR, XOR, XNOR, and inverter) that performs a specific function. For example, the logic cell may include transistors for constituting a logic device, and may also include wiring lines that connect the transistors to each other.

The single height cell may include a first active region AR1 and a second active region AR2 on the substrate 200. The first and second active regions AR1 and AR2 may extend in a first direction D1 and may be spaced apart from each other in a second direction D2. The first and second directions D1 and D2 may be parallel to a top surface of the substrate 200, and may intersect each other. For example, the first active region AR1 may be an NMOSFET region, and the second active region AR2 may be a PMOSFET region.

A first active pattern AP1 may be provided in the first active region AR1. A second active pattern AP2 may be provided in the second active region AR2. Each of the first and second active patterns AP1 and AP2 may be defined by a trench TR on an upper portion of the substrate 200. The first and second active patterns AP1 and AP2 may be provided on the substrate 200. For example, the first and second active patterns AP1 and AP2 may protrude in a third direction D3 from the top surface of the substrate 200. The third direction D3 may be perpendicular to the top surface of the substrate 200. The first active pattern AP1 may include a plurality of first active patterns AP1 that are disposed spaced apart from each other in the first direction D1. The second active pattern AP2 may include a plurality of second active patterns that are disposed spaced apart from each other in the second direction D2. Each of the first and second active patterns AP1 and AP2 may include at least one selected from silicon (Si), germanium (Ge), and silicon-germanium (SiGe).

A device isolation pattern may be provided on the substrate 200, filling the trench TR. The device isolation pattern may surround the first active patterns AP1 and the second active patterns AP2. The device isolation pattern may include a dielectric material.

A first channel pattern CH1 may be provided on the first active pattern AP1, and a second channel pattern CH2 may be provided on the second active pattern AP2. The first channel pattern CH1 may be provided in plural, and the plurality of first channel patterns CH1 may be spaced apart from each other in the first direction D1. The second channel pattern CH2 may be provided in plural, and the plurality of second channel patterns CH2 may be spaced apart from each other in the first direction D1. Each of the first and second channel patterns CH1 and CH2 may include a first semiconductor pattern SP1, a second semiconductor pattern SP2, and a third semiconductor pattern SP3 that are arranged and spaced apart from each other in the third direction D3, but the present disclosure is not limited thereto. Each of the first and second channel patterns CH1 and CH2 may include, for example, four or more semiconductor patterns. Each of the first, second, and third semiconductor patterns SP1, SP2, and SP3 may include, for example, crystalline silicon.

First recesses RS1 may be defined between the first channel patterns CH1 that neighbor each other in the first direction D1. Second recesses RS2 may be defined between the second channel patterns CH2 that neighbor each other in the first direction D1.

A first source/drain pattern SD1 may be provided on the first active pattern AP1, and a second source/drain pattern SD2 may be provided on the second active pattern AP2. The first source/drain pattern SD1 may fill the first recess RS1, and the second source/drain pattern SD2 may fill the second recess RS2. Each of the first and second source/drain patterns SD1 and SD2 may be connected to the first, second, and third semiconductor patterns SP1, SP2, and SP3.

A plurality of first source/drain patterns SD1 may be impurity regions having a first conductivity type (e.g., n-type), and a plurality of second source/drain patterns SD2 may be impurity regions having a second conductivity type (e.g., p-type). For example, a pair of first source/drain patterns SD1 that neighbor in the first direction D1 may be connected to each other through the first channel pattern CH1. For example, a pair of second source/drain patterns SD2 that neighbor in the first direction D1 may be connected to each other through the second channel pattern CH2.

The first source/drain patterns SD1 may include the same semiconductor element (e.g., Si) as that of the first channel pattern CH1. The second source/drain patterns SD2 may include a semiconductor element (e.g., SiGe) whose lattice constant is greater than that of a semiconductor element of the second channel pattern CH2. Therefore, a pair of neighboring second source/drain patterns SD2 may provide a compressive stress to the second channel pattern CH2 therebetween.

The second source/drain pattern SD2 may include a buffer layer BFL that covers an inner surface of the second recess RS2 and a main layer MAL that fills most of an unoccupied portion of the second recess RS2. For example, each of the buffer layer BFL and the main layer MAL may include silicon-germanium (SiGe). The buffer layer BFL may contain a relatively low concentration of germanium (Ge). The main layer MAL may contain a relatively high concentration of germanium (Ge). Alternatively, the buffer layer BFL may contain only silicon (Si).

An inner gate spacer IGS may be interposed between the first source/drain pattern SD1 and a gate electrode GE. The gate electrode GE will be discussed below. The inner gate spacer IGS may include, for example, a dielectric material.

A gate electrode GE may be provided on and run across each of the first channel pattern CH1 and the second channel pattern CH2. The gate electrode GE may be provided in plural. The plurality of gate electrodes GE may each extend in the second direction D2, and may be spaced apart from each other in the first direction D1.

The gate electrode GE may include an inner electrode PO1 and an outer electrode PO2. The inner electrode PO1 of the gate electrode GE may be provided between an uppermost semiconductor pattern SP3 among the plurality of semiconductor patterns SP1, SP2, and SP3 and the first and second active patterns AP1 and AP2. The outer electrode PO2 of the gate electrode GE may be provided on the uppermost semiconductor pattern SP3. The inner electrode PO1 of the gate electrode GE may include three electrode portions, but the present disclosure is not limited thereto. For example, the inner electrode PO1 of the gate electrode GE may include four or more electrode portions.

The gate electrode GE may include a first metal pattern and a second metal pattern on the first metal pattern. The first metal pattern may include a work-function metal that controls a threshold voltage of a transistor. For example, the first metal pattern may include at least one selected from metallic materials (e.g., Ti, Mo, W, Cu, Al, Ta, Ru, Ir, or Co) and metal nitrides (e.g., nitride of Ti, Mo, W, Cu, Al, Ta, Ru, Ir, or Co). The first metal pattern may further include carbon (C). The first metal pattern may include metallic materials whose work-function materials are different from each other.

The second metal pattern may include a metallic material (e.g., Ti, Mo, W, Cu, Al, Ta, Ru, Ir, or Co) whose resistance is less than that of the first metal pattern.

The inner electrode PO1 of the gate electrode GE may include a first metal pattern. The outer electrode PO2 of the gate electrode GE may include a first metal pattern and a second metal pattern.

A gate capping pattern GP may be provided on a top surface of the gate electrode GE. For example, the gate capping pattern GP may include at least one selected from SiON, SiCN, SiCON, and SiN.

Outer gate spacers OGS may be provided on lateral surfaces of the outer electrode PO2 of the gate electrode GE, and may extend onto lateral surfaces of the gate capping pattern GP. The outer gate spacer OGS may include a single layer or multiple layers. For example, the outer gate spacer OGS may include at least one selected from SiON, SiCN, SiOCN, and SiN.

A gate dielectric pattern GI may be interposed between the gate electrode GE and the first, second, and third semiconductor patterns SP1, SP2, and SP3. The gate dielectric pattern GI may cover a top surface, a bottom surface, and opposite lateral surfaces of each of the first, second, and third semiconductor patterns SP1, SP2, and SP3. The gate dielectric pattern GI may be interposed between the outer electrode PO2 and the outer gate spacer OGS. For example, the gate dielectric pattern GI may include at least one selected from silicon oxide (SiO₂), silicon oxynitride (SiON), and high-k dielectric materials. In this disclosure, the expression “high-k dielectric material” indicates a material whose dielectric constant is greater than that of silicon oxide.

A first interlayer dielectric layer ILD1 may be provided on the substrate 200. The first interlayer dielectric layer ILD1 may cover the outer gate spacers OGS and the first and second source/drain patterns SD1 and SD2. For example, the first interlayer dielectric layer ILD1 may have a top surface located at substantially the same level as that of a top surface of the gate capping pattern GP and that of a top surface of the outer gate spacer OGS.

The first interlayer dielectric layer ILD1 may be provided thereon with a second interlayer dielectric layer ILD2 that covers the gate capping pattern GP. A third interlayer dielectric layer ILD3 may be provided on the second interlayer dielectric layer ILD2. For example, the first, second, and third interlayer dielectric layers ILD1, ILD2, and ILD3 may include silicon oxide (SiO₂).

In accordance with a circuit design of the single height cell, an active contact may penetrate the first and second interlayer dielectric layers ILD1 and ILD2, and a lower portion of the active contact may be buried in an upper portion of at least one selected from the first source/drain patterns SD1 and the second source/drain patterns SD2, but the present disclosure is not limited thereto. Alternatively, the active contact may be omitted from an inside of the single height cell. The source/drain pattern SD1 or SD2 that is not connected to the active contact may be connected to a backside conductive contact BCA which will be discussed below.

For example, the active contact may include at least one selected from metallic materials (e.g., Ti, Mo, W, Cu, Al, Ta, Ru, Ir, and Co), metal nitride (e.g., nitride of Ti, Mo, W, Cu, Al, Ta, Ru, Ir, or Co), and metal silicide (e.g., silicide of Ti, Mo, W, Cu, Al, Ta, Ru, or Ir).

Gate contacts GC may penetrate in the third direction D3 through the second interlayer dielectric layer ILD2 and the gate capping pattern GP. Each of the gate contacts GC may be buried in an upper portion of the outer electrode PO2 of the gate electrode GE. For example, the gate contacts GC may include at least one selected from metallic materials (e.g., Ti, Mo, W, Cu, Al, Ta, Ru, Ir, or Co) and metal nitrides (e.g., nitride of Ti, Mo, W, Cu, Al, Ta, Ru, Ir, or Co).

A separation pattern DB may be provided on a lateral surface of each of the first active region AR1 and the second active region AR2. The separation pattern DB may be provided in plural, and the plurality of separation patterns DB may each extend along the second direction D2 and may be spaced apart from each other in the first direction D1. The first active region AR1 may be provided between the separation patterns DB that neighbor each other in the first direction D1. The second active region AR2 may be provided between the separation patterns DB that neighbor each other in the first direction D1. The separation patterns DB may include a dielectric material. The separation pattern DB may electrically separate the single height cell from other logic cells that neighbor each other in the first direction D1. When viewed in a direction parallel to the top surface of the substrate 200, a width of the separation pattern DB may increase in the third direction D3.

Metal patterns MT may be provided in the third interlayer dielectric layer ILD3. Via patterns VI may be interposed between the metal patterns MT and the gate contacts GC. The metal patterns MT may be connected through the via patterns VI to the gate contacts GC. Each of the metal patterns MT and the via patterns VI may be provided in plural layers, and the metal patterns MT and the via patterns VI may be alternately stacked. The metal patterns MT and the via patterns VI may include a metallic material (e.g., Ti, Mo, W, Cu, Al, Ta, Ru, Ir, or Co).

A pillar pattern IP may be provided on the substrate 200. The pillar pattern IP may be interposed between the first active patterns AP1, and may separate the first active patterns AP1 from each other. The pillar pattern IP may be interposed between the second active patterns AP2, and may separate the second active patterns AP2 from each other. The pillar pattern IP may be provided beneath and vertically overlap the first, second, and third semiconductor patterns SP1, SP2, and SP3. The pillar pattern IP may be provided beneath and vertically overlap the inner electrodes PO1 of the gate electrode GE. A top surface of the pillar pattern IP may be in contact with the gate dielectric pattern GI that cover a lowermost one of the inner electrodes PO1 of the gate electrode GE. The gate dielectric pattern GI may separate the pillar pattern IP from the lowermost one of the inner electrodes PO1 of the gate electrode GE. The pillar pattern IP may include a dielectric material. For example, the pillar pattern IP may include at least one selected from SiO₂, SiN, SiON, and SiOC.

The pillar pattern IP may be provided in plural. The plurality of pillar patterns IP may be disposed spaced apart from each other in the first direction D1, and may each extend in the second direction D2. When viewed in a direction parallel to the top surface of the substrate 200, a width of the pillar pattern IP may decrease in the third direction D3.

A backside conductive contact BCA may be interposed between the first source/drain pattern SD1 and a power rail MPR (which will be discussed below) or between the second source/drain pattern SD2 and the power rail MPR. The power rail MPR may be connected through the backside conductive contact BCA to each of the first source/drain pattern SD1 and the second source/drain pattern SD2. The backside conductive contact BCA may be interposed between the pillar patterns IP that neighbor each other in the first direction D1. The backside conductive contact BCA may be interposed between the pillar pattern IP and the separation pattern DB that neighbor each other in the first direction D1. The backside conductive contact BCA may be provided in plural. Below the first active region AR1, the backside conductive contacts BCA may be spaced apart from each other in the first direction D1. Below the second active region AR2, the backside conductive contacts BCA may be spaced apart from each other in the first direction D1.

The backside conductive contact BCA may include a conductive material, such as metal. For example, the backside conductive contact BCA may include at least one selected from metallic materials (e.g., Ti, Mo, W, Cu, Al, Ta, Ru, Ir, or Co) and metal nitrides (e.g., nitride of Ti, Mo, W, Cu, Al, Ta, Ru, Ir, or Co).

The backside conductive contact BCA may include an upper portion UP that penetrates the first active pattern AP1 or the second active pattern AP2, and a lower portion LP between the upper portion UP and a power rail MPR which will be discussed below. A part of the upper portion UP of the backside conductive contact BCA may be inserted into the first source/drain pattern SD1 or the second source/drain pattern SD2. The upper portion UP of the backside conductive contact BCA may be in contact with the first active pattern AP1 or the second active pattern AP2.

The backside conductive contact BCA may have a step difference between the lower portion LP and the upper portion UP. A subsequently described liner pattern IL may separate the lower portion LP of the backside conductive contact BCA from the first active pattern AP1 or the second active pattern AP2.

A liner pattern IL may be provided on the pillar pattern IP. The liner pattern IL may be interposed between the first active pattern AP1 and the backside conductive contact BCA and between the second active pattern AP2 and the backside conductive contact BCA. The liner pattern IL may be interposed between the backside conductive contact BCA and the pillar pattern IP. Between the first active pattern AP1 and the backside conductive contact BCA, the liner pattern IL may extend between the backside conductive contact BCA and the pillar pattern IP. Between the second active pattern AP2 and the backside conductive contact BCA, the liner pattern IL may extend between the backside conductive contact BCA and the pillar pattern IP. The liner pattern IL may include a dielectric material. For example, the liner pattern IL may include at least one selected from SiN and SiON. The liner pattern IL may include a material different from that of the pillar pattern IP, but the present disclosure is not limited thereto. For example, the liner pattern IL may include the same material as that of the pillar pattern IP. The liner pattern IL and the pillar pattern IP may integrally form a single unitary shape.

The liner pattern IL may include a first portion P1 that covers a top surface La of the lower portion LP of the backside conductive contact BCA and a second portion P2 that extends from the first portion P1 and along a sidewall of the lower portion LP of the backside conductive contact BCA. The first portion P1 of the liner pattern IL may be interposed between the first active pattern AP1 and the lower portion LP of the backside conductive contact BCA and between the second active pattern AP2 and the lower portion LP of the backside conductive contact BCA. The second portion P2 of the liner pattern IL may be interposed between the pillar pattern IP and the lower portion LP of the backside conductive contact BCA. The second portion P2 of the liner pattern IL may separate the lower portion LP of the backside conductive contact BCA from the pillar pattern IP.

The second portion P2 of the liner pattern IL may cover a lateral surface of a lower portion of the pillar pattern IP. The second portion P2 of the liner pattern IL may cover opposite lateral surfaces of the lower portion LP of the backside conductive contact BCA. The second portion P2 of the liner pattern IL may extend from the first portion P1 of the liner pattern IL to a top surface of a power rail MPR which will be discussed below. For example, the second portion P2 of the liner pattern IL may be in contact with a top surface of a power rail MPR. The second portion P2 of the liner pattern IL may include a pair of second portions P2 that neighbor each other in the first direction D1 between the pillar patterns IP that neighbor each other in the first direction D1. The pair of second portions P2 of the liner pattern IL may be connected to each other through the first portion P1 of the liner pattern IL. The first portion P1 and the pair of second portions P2 of the liner pattern IL may be successively connected to each other.

A power rail MPR may be buried in the substrate 200. The power rail MPR may be provided beneath the backside conductive contacts BCA. The power rail MPR may be connected through the backside conductive contact BCA to the first source/drain pattern SD1. The power rail MPR may be connected through the backside conductive contact BCA to the first source/drain pattern SD1. The power rail MPR may extend in a direction along which the backside conductive contacts BCA are disposed. The power rail MPR may include a conductive material, such as metal.

A power delivery network layer PDN may be provided on a bottom surface of the substrate 200. The power delivery network layer PDN may include a plurality of lower wiring lines that are connected through the power rail MPR and the backside conductive contact BCA to the first source/drain patterns SD1 and the second source/drain patterns SD2. The power delivery network layer PDN may include a wiring network for applying a source voltage. The power delivery network layer PDN may include a wiring network for applying a drain voltage.

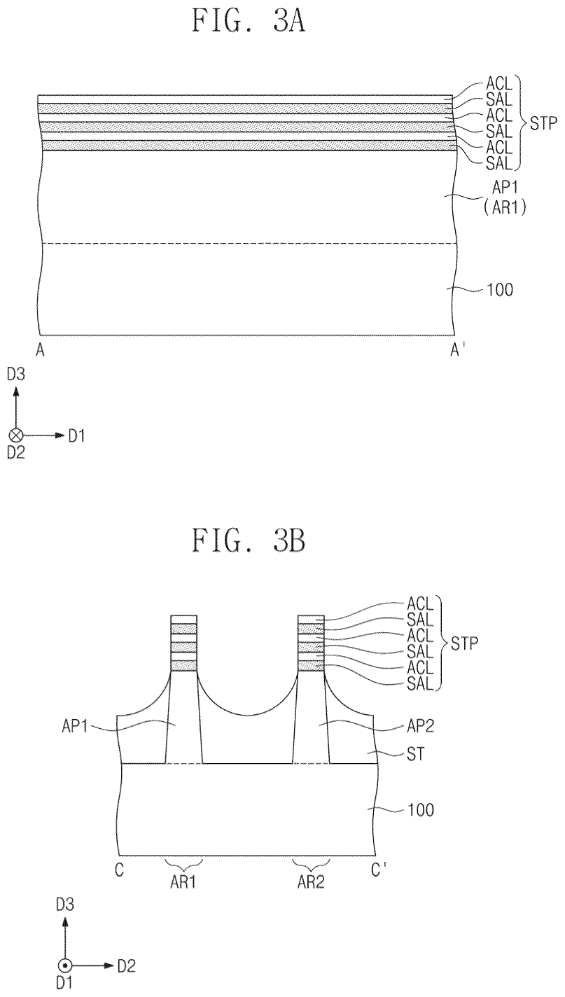

With reference to FIGS. 3A to 9, the following will describe a method of fabricating a semiconductor device according to one or more embodiments of the present disclosure. For brevity of description, an explanation of components repetitive to those discussed above will be omitted, and a difference thereof will be discussed in detail.

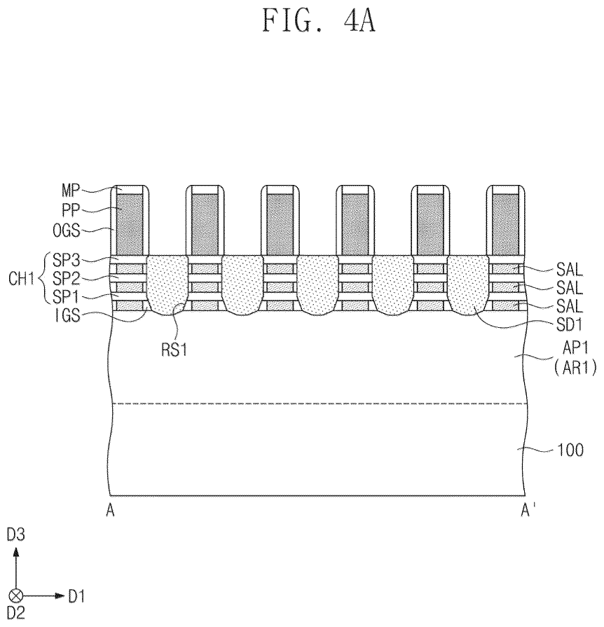

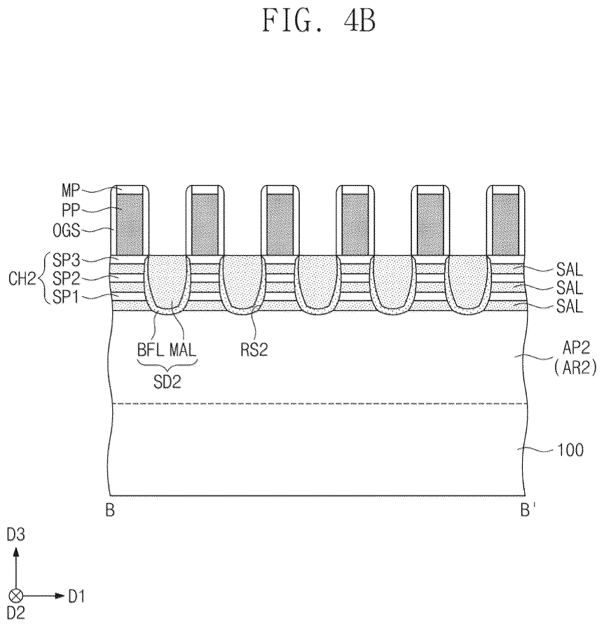

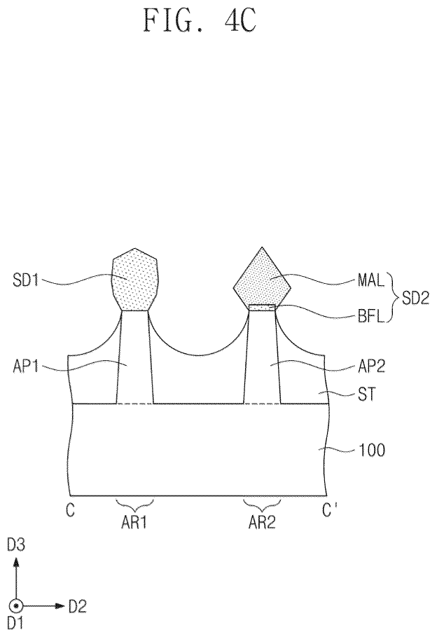

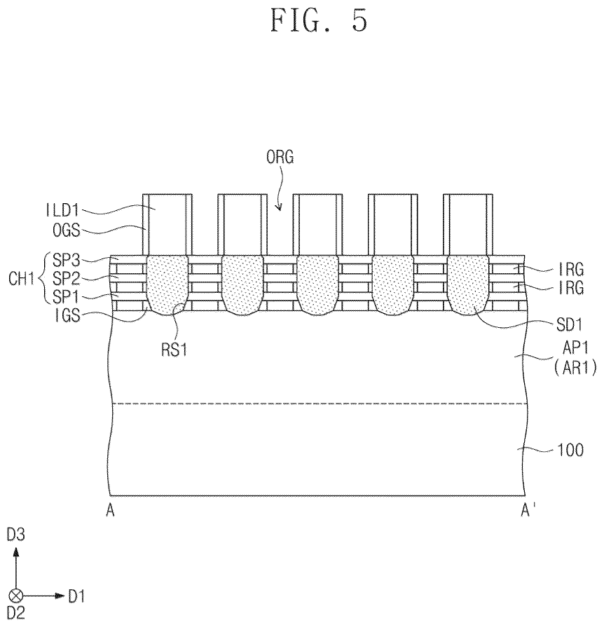

FIGS. 3A to 9 illustrate cross-sectional views showing a method of fabricating a semiconductor device according to one or more embodiments of the present disclosure. In detail, FIGS. 3A, 4A, 5, 6, 7, 8, and 9 illustrate cross-sectional views taken along line A-A′ of FIG. 1. FIG. 4B illustrates a cross-sectional view taken along line B-B′ of FIG. 1. FIGS. 3B and 4C illustrate cross-sectional views taken along line C-C′ of FIG. 1.

Referring to FIGS. 1, 3A, and 3B, a semiconductor substrate 100 may be provided which includes a first active region AR1 and a second active region AR2. For example, the semiconductor substrate 100 may be a semiconductor substrate including a semiconductor material, such as a monocrystalline silicon substrate, a silicon-germanium substrate, or silicon-on-insulator (SOI) substrate. Stack patterns STP may be formed on the first active region AR1 and the second active region AR2. For example, the formation of the stack patterns STP may include alternately stacking semiconductor layers ACL and sacrificial layers SAL on the semiconductor substrate 100, forming mask patterns that extend in a first direction D1, and using the mask patterns as an etching mask to perform a patterning process. In the patterning process, a part of the semiconductor substrate 100 may be removed, and trenches TR may be formed to define a first active pattern AP1 and a second active pattern AP2. Device isolation patterns ST may be formed to fill the trenches TR.

The sacrificial layers SAL may include a material having an etch selectivity with respect to the semiconductor layers ACL. Thus, even when the sacrificial layers SAL are removed in a process which will be discussed below, the semiconductor layers ACL may not be removed or may be slightly removed. For example, the semiconductor layers ACL may include one of silicon (Si), germanium (Ge), and silicon-germanium (SiGe), and the sacrificial layers SAL may include another of silicon (Si), germanium (Ge), and silicon-germanium (SiGe).

Referring to FIGS. 1 and 4A to 4C, sacrificial patterns PP may be formed to extend along a second direction D2 on the semiconductor substrate 100. The sacrificial patterns PP may be formed to cover top surfaces of the device isolation patterns ST and also to cover lateral and top surfaces of the stack patterns STP. For example, the formation of the sacrificial patterns PP may include forming a sacrificial layer on a front surface of the semiconductor substrate 100, forming hardmask patterns MP on the sacrificial layer, and using the hardmask patterns MP as an etching mask to remove a part of the sacrificial layer to form the sacrificial patterns PP. The sacrificial pattern PP may include polysilicon. Afterwards, outer gate spacers OGS may be formed on lateral surfaces of the sacrificial patterns PP.

First recesses RS1 may be formed in the stack pattern STP on the first active pattern AP1. Second recesses RS2 may be formed in the stack pattern STP on the second active pattern AP2. For example, the first recess RS1 and the second recess RS2 may be formed by using the hardmask patterns MP as an etching mask to remove a part of the stack pattern STP.

The first recesses RS1 may separate the semiconductor layers ACL on the first active pattern AP1 into first channel patterns CH1 that are spaced apart from each other in the first direction D1. The second recesses RS2 may separate the semiconductor layers ACL on the second active pattern AP2 into second channel patterns CH2 that are spaced apart from each other in the first direction D1. Each of the first and second channel patterns CH1 and CH2 may include first, second, and third semiconductor patterns SP1, SP2, and SP3.

First source/drain patterns SD1 may be formed in the first recesses RS1. The first source/drain patterns SD1 may be formed by selective epitaxial growth in which the first, second, and third semiconductor patterns SP1, SP2, and SP3, and the semiconductor substrate 100 on the first active region AR1, are used as seeds.

During the formation of the first source/drain pattern SD1, impurities (e.g., phosphorus, arsenic, or antimony) may be implanted in situ to allow the first source/drain pattern SD1 to have an n-type conductivity type. Alternatively, after the formation of the first source/drain pattern SD1, the impurities may be implanted into the first source/drain pattern SD1.

Second source/drain patterns SD2 may formed in the second recesses RS2. The second source/drain patterns SD2 may be formed by selective epitaxial growth in which the first, second, and third semiconductor patterns SP1, SP2, and SP3, and the semiconductor substrate 100 on the second active region AR2, are used as seeds.

For example, during the formation of the second source/drain pattern SD2, impurities (e.g., boron, gallium, or indium) may be implanted in situ to allow the second source/drain pattern SD2 to have a p-type conductivity type. Alternatively, after the formation of the second source/drain pattern SD2, the impurities may be implanted into the second source/drain pattern SD2.

Referring to FIGS. 1 and 5, a first interlayer dielectric layer ILD1 may be formed to cover the first source/drain pattern SD1, the second source/drain pattern (see SD2 of FIGS. 4B and 4C), the hardmask patterns MP, and the outer gate spacers OGS. After that, the first interlayer dielectric layer ILD1 may be removed on top surfaces of the sacrificial patterns PP. In the removal process, the hardmask patterns MP may also be removed, and the sacrificial patterns PP may be exposed.

Thereafter, the exposed sacrificial patterns PP may be removed, and an outer region ORG may be formed on a region where the sacrificial patterns PP are removed. The outer region ORG may outwardly expose the first channel pattern CH1, the second channel pattern (see CH2 of FIG. 4B), and the sacrificial layers SAL.

The exposed sacrificial layers SAL may be selectively removed. In this stage, the first, second, and third semiconductor patterns SP1, SP2, and SP3 may not be removed or may be slightly removed due to a high etch selectivity of the sacrificial layers SAL.

Inner regions IRG may be formed on regions where the sacrificial layers SAL are removed. For example, the inner regions IRG may be formed between the first, second, and third semiconductor patterns SP1, SP2, and SP3.

A gate dielectric pattern GI may be formed in each of the inner regions IRG and the outer region ORG. The gate dielectric pattern GI may be formed to surround each of the first, second, and third semiconductor patterns SP1, SP2, and SP3.

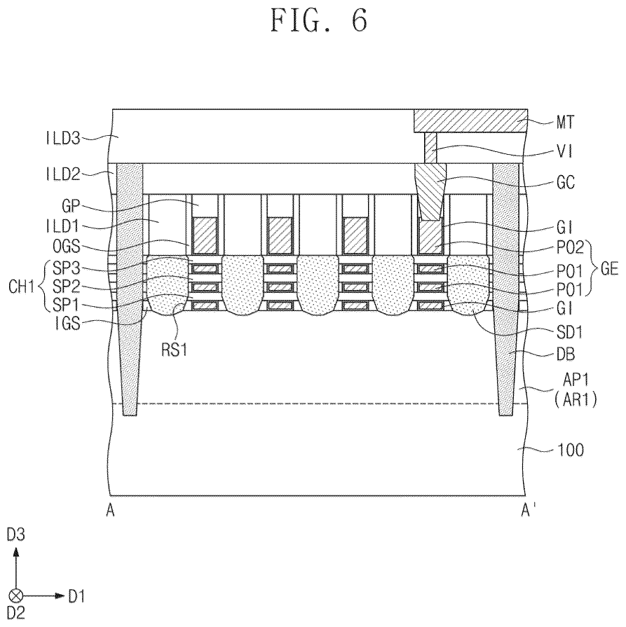

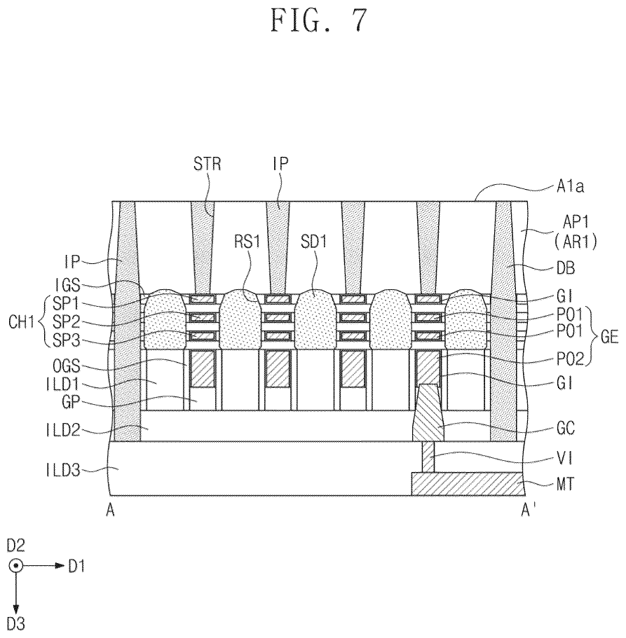

Referring to FIGS. 1 and 6, a gate electrode GE may be formed on the gate dielectric pattern GI. The gate electrode GE may include an inner electrode PO1 formed in each of the inner regions IRG and an outer electrode PO2 formed in the outer region ORG. A gate capping pattern GP may be formed on the outer electrode PO2 of the gate electrode GE.

A separation pattern DB may be formed to penetrate the first interlayer dielectric layer ILD1. The separation pattern DB may be formed to penetrate the first channel pattern CH1 and the first active region AR1. The separation pattern DB may be formed to penetrate the second channel pattern (see CH2 of FIG. 4B) and the second active region AR2.

A second interlayer dielectric layer ILD2 may be formed on the first interlayer dielectric layer ILD1 and the gate capping pattern GP.

Gate contacts GC may be formed to penetrate the second interlayer dielectric layer ILD2 and the gate capping pattern GP and to connect with the gate electrodes GE.

A third interlayer dielectric layer ILD3 may be formed on the second interlayer dielectric layer ILD2. Metal patterns MT and via patterns VI may be formed in the third interlayer dielectric layer ILD3.

Referring to FIGS. 1 and 7, after the back-end-of-line (BEOL) process is completed, the semiconductor substrate 100 discussed with reference to FIGS. 3A and 3B may be flipped or turned upside down. Thus, a bottom surface of the semiconductor substrate (see 100 of FIGS. 3A and 3B) may be exposed. As the semiconductor substrate (see 100 of FIGS. 3A and 3B) is turned upside down, in subsequently describing a method of fabricating a semiconductor device with reference to FIGS. 7 to 9, the language “top surface” and “upper portion” may respectively refer to “bottom surface” and “lower portion” in a semiconductor device completely fabricated with reference to FIGS. 2A and 2B, and the language “bottom surface” and “lower portion” may respectively refer to “top surface” and “upper portion” in a semiconductor device fabricated with reference to FIGS. 2A and 2B.

In the following method of fabricating a semiconductor device, various components formed on the first active region AR1 of a single height cell will be described for the sake of convenience, but the following description will be identically applied to other various components formed on the second active region AR2.

A planarization process may be performed on the exposed surface of the semiconductor substrate (see 100 of FIGS. 3A and 3B) to remove the semiconductor substrate 100. Therefore, the separation pattern DB may be formed to have a top surface substantially coplanar with a top surface Ala of the first active pattern AP1.

A part of the first active pattern AP1 may be removed to form a separation trench STR on each of the first channel patterns CH1. The separation trench STR may be formed to penetrate the first active pattern AP1. For example, the separation trench STR may be formed not to penetrate the gate dielectric pattern GI. The separation trench STR may separate the first active pattern AP1 into first active patterns AP1 that are disposed spaced apart from each other in the first direction D1. As the separation trench STR separates the first active patterns AP1, it may be possible to prevent a leakage current through the first active patterns AP1 to the first source/drain patterns SD1. In the present disclosure, the leakage current may be prevented by the formation of only the separation trench STR without completely removing the first active pattern AP1. As a result, a removal process of the semiconductor substrate (see 100 of FIGS. 3A and 3B) and the first active pattern AP1 may be simplified to increase productivity of semiconductor devices.

A pillar pattern IP may be formed to fill the separation trench STR. The formation of the pillar pattern IP may include, for example, forming a preliminary pillar layer that fills the separation trench STR and covers the top surfaces Ala of the first active patterns AP1, and performing a removal process on an upper portion of the preliminary pillar layer. For example, after the removal process of the upper portion of the preliminary pillar layer, a top surface of the pillar pattern IP may be substantially coplanar with the top surface Ala of each of the first active patterns AP1.

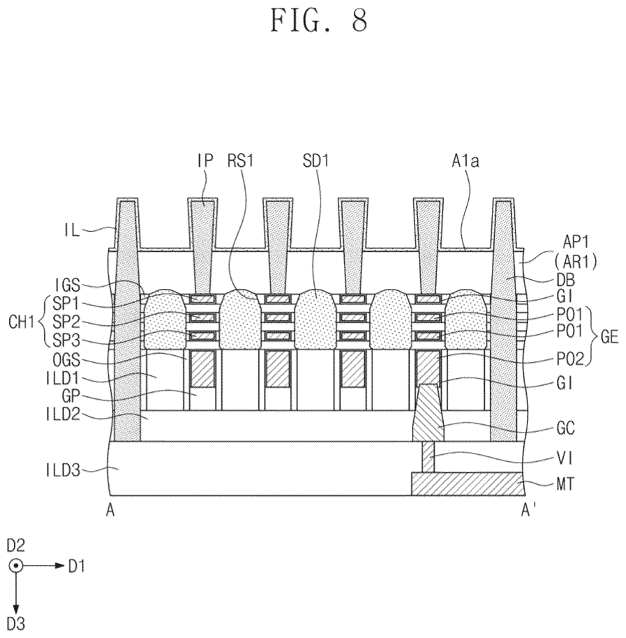

Referring to FIGS. 1 and 8, a removing process may be performed on an upper portion of each of the first active patterns AP1. Thus, the top surface Ala of each of the first active patterns AP1 may be positioned between the top and bottom surfaces of the pillar pattern IP.

According to the present disclosure, after the semiconductor substrate (see 100 of FIGS. 3A and 3B) is turned upside down, the removal process on the upper portions of each of the first active patterns AP1 may be performed after the formation of the separation trenches STR and the formation of the pillar patterns IP. In contrast, when the removal process is performed before the formation of the pillar patterns IP, the top surface Ala of the first active pattern AP1 may be located at an irregular level. Thus, when the separation trenches STR are formed in a subsequent process, the gate dielectric pattern GI may be perforated, and the gate electrode GE may be exposed. In addition, when the removal process is performed before the formation of the pillar patterns IP, a part of the material in the separation pattern DB may also be unnecessarily removed. Therefore, when a backside conductive contact BCA is subsequently formed, a conductive material may be formed in the separation pattern DB, and thus process failure may occur. In a fabrication method of the present disclosure, the removal process on the upper portion of each of the first active patterns AP1 may be performed after the formation of the separation trenches STR and the formation of the pillar patterns IP, and thus the above-mentioned process failure may be prevented. Accordingly, the process of the current disclosure may improve semiconductor device fabrication productivity.

Furthermore, when the pillar pattern IP is formed, it is not required that a mask pattern be separately provided. In contrast, when a mask pattern is provided to form the pillar pattern IP, the mask pattern may be vulnerable to high temperatures. Thus, the mask pattern may be formed to have an abnormal shape due to high temperatures occurring when the pillar pattern IP is formed. As a result, the pillar pattern IP formed in the mask pattern may have an abnormal shape, and afterwards, a backside conductive contact BCA may be formed to have an abnormal shape between the pillar patterns IP. In the present disclosure, a mask pattern is not required to form the pillar pattern IP in the separation trench STR provided between the first active patterns AP1, thereby preventing the problems discussed above. Accordingly, the process of the current disclosure may improve semiconductor device fabrication productivity as well as semiconductor device electrical properties.

A liner pattern IL may be formed to conformally cover the top and lateral surfaces of the pillar patterns IP, the top surfaces Ala of the first active patterns AP1, the top and lateral surfaces of the separation patterns DB.

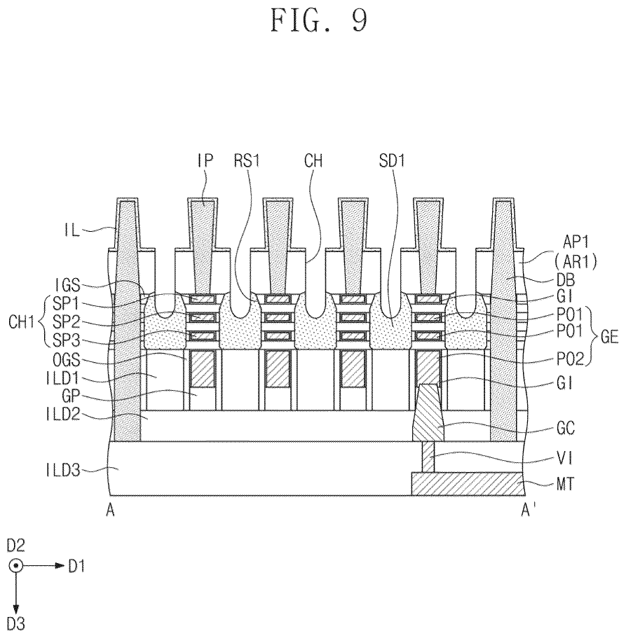

Referring to FIGS. 1 and 9, a removal process may be performed on a part of the liner pattern IL and a part of each of the first active patterns AP1, such that contact holes CH may be formed on the first source/drain patterns SD1. During the removal process, a part of each of the first source/drain patterns SD1 may also be removed. The contact hole CH may outwardly expose a top surface of the first source/drain pattern SD1.

Referring to FIGS. 1 and 2A, backside conductive contacts BCA may be formed in the contact holes (see CH of FIG. 9). The backside conductive contacts BCA may be formed to fill regions between the first active patterns AP1. The backside conductive contacts BCA may be formed to fill between the first active pattern AP1 and the separation pattern DB.

When the backside conductive contacts BCA are formed, a process may also be performed to remove a part of the liner pattern IL (e.g., a region of the liner pattern IL on the top surface of each of the separation pattern DB and the pillar pattern IP in FIG. 9).

A substrate 200 may be formed to cover the backside conductive contacts BCA. A power rail MPR may be formed in the substrate 200. A power delivery network layer PDN may be formed on the substrate 200.

According to the present disclosure, after a semiconductor substrate is turned upside down, a removal process on an upper portion of each of active patterns may be performed after the formation of separation trenches and the formation of pillar patterns. By contrast, when the removal process is performed before the formation of pillar patterns, top surfaces of the active patterns may be located at irregular levels. Therefore, when separation trenches are subsequently provided, a gate dielectric pattern may be perforated, and a gate electrode may be exposed. In addition, when the removal process is performed before the formation of pillar patterns, a part of material in the separation pattern may also be unnecessarily removed.

Therefore, when a backside conductive contact is subsequently formed, a conductive material may be formed in the separation pattern, and thus process failure may occur. In a fabrication process of the present disclosure, the removal process on the upper portion of each of the active patterns may be performed after the formation of separation trenches and the formation of pillar patterns, and thus the process failures noted above may be prevented. Accordingly, a semiconductor device fabrication process may have improved productivity.

Furthermore, when the pillar pattern is formed in the process of the present disclosure, it is not necessary to separately provide a mask pattern. By contrast, when a mask pattern is separately provided to form the pillar pattern, the mask pattern may be vulnerable to high temperatures, which may result in the mask pattern having an abnormal shape due to high temperatures occurring when the pillar pattern is formed. As a result, the pillar pattern formed in the mask pattern may have an abnormal shape, and afterwards, a backside conductive contact may be formed to have an abnormal shape between the pillar patterns. In the present disclosure, it is not required that a mask pattern be separately used to form the pillar pattern in the separation trench provided between the first active patterns, thereby preventing the problems discussed above. Accordingly, a semiconductor device fabrication process may have improved productivity and result in semiconductor devices having improved electrical properties.

The above embodiments have been described for a nanosheet transistor structure in which a plurality of semiconductor patterns arranged in the third direction D3 form a channel pattern of a nanosheet transistor also referred to as gate-all-around (GAA) transistor. However, the disclosure is not limited thereto, and thus, the above embodiments may also apply to different types of field-effect transistors including a fin-field-effect transistor (FinFET) structure or forksheet transistor structure, not being limited thereto, with minimal modification if necessary.

The aforementioned description provides one or more embodiments for explaining the present disclosure. Therefore, the present disclosure is not limited to the embodiments described above, and it will be understood by one of ordinary skill in the art that variations in form and detail may be made therein without departing from the spirit and essential features of the present disclosure.

What is claimed is:

1. A semiconductor device comprising:
a plurality of active patterns on a substrate;
a source/drain pattern on the substrate;
a power rail in the substrate;
a pillar pattern between the plurality of active patterns;
a channel pattern on the pillar pattern;
a backside conductive contact between the source/drain pattern and the power rail; and
a liner pattern on the pillar pattern,
wherein the liner pattern comprises:
a first portion that covers a top surface of a lower portion of the backside conductive contact; and
a second portion that extends from the first portion and along a sidewall of the lower portion of the backside conductive contact.

2. The semiconductor device of claim 1, wherein the second portion of the liner pattern separates the pillar pattern from the lower portion of the backside conductive contact.

3. The semiconductor device of claim 1, wherein the second portion of the liner pattern is between the pillar pattern and the lower portion of the backside conductive contact.

4. The semiconductor device of claim 1, wherein the second portion of the liner pattern covers a lateral surface of a lower portion of the pillar pattern.

5. The semiconductor device of claim 1, wherein the second portion of the liner pattern extends from the first portion of the liner pattern to a top surface of the power rail.

6. The semiconductor device of claim 1, wherein the second portion of the liner pattern is in contact with the power rail.

7. The semiconductor device of claim 1, wherein the second portion of the liner pattern covers opposite lateral surfaces of the lower portion of the backside conductive contact.

8. The semiconductor device of claim 1,
wherein the second portion of the liner pattern comprises a pair of second portions that neighbor each other in a first direction parallel to a top surface of the substrate, and
wherein the pair of second portions are connected to each other through the first portion of the liner pattern.

9. The semiconductor device of claim 1, wherein the first portion of the liner pattern is between the plurality of active patterns and the lower portion of the backside conductive contact.

10. The semiconductor device of claim 1, wherein a width of the pillar pattern decreases in a direction perpendicular to a top surface of the substrate.

11. The semiconductor device of claim 1,
wherein the backside conductive contact comprises a plurality of backside conductive contacts that are disposed along a first direction parallel to a top surface of the substrate, and
wherein the pillar pattern is between the plurality of backside conductive contacts.

12. The semiconductor device of claim 1, wherein the pillar pattern separates the plurality of active patterns from each other.

13. A semiconductor device comprising:
a plurality of active patterns on a substrate;
a source/drain pattern on the substrate;
a power rail in the substrate;
a pillar pattern between the plurality of active patterns;
a channel pattern on the pillar pattern;
a backside conductive contact between the source/drain pattern and the power rail; and
a liner pattern between the pillar pattern and a lower portion of the backside conductive contact.

14. The semiconductor device of claim 13, wherein the liner pattern separates the pillar pattern from the lower portion of the backside conductive contact.

15. The semiconductor device of claim 13, wherein the liner pattern covers a lateral surface of a lower portion of the pillar pattern.

16. The semiconductor device of claim 13, wherein, between the pillar pattern and the lower portion of the backside conductive contact, the liner pattern extends between the plurality of active patterns and the lower portion of the backside conductive contact.

17. The semiconductor device of claim 13, wherein the liner pattern comprises:
a first portion that covers a top surface of the lower portion of the backside conductive contact; and
a second portion that extends from the first portion and along a sidewall of the lower portion of the backside conductive contact.

18. The semiconductor device of claim 13, wherein the liner pattern covers opposite lateral surfaces of the lower portion of the backside conductive contact.

19. The semiconductor device of claim 13, wherein the liner pattern extends to a top surface of the power rail from a bottom surface of one of the plurality of active patterns.

20. A semiconductor device comprising:
a plurality of active patterns on a substrate;
a source/drain pattern on the substrate;
a power delivery network layer on a bottom surface of the substrate;
a power rail in the substrate;
a pillar pattern between the plurality of active patterns;
a channel pattern on the pillar pattern;
a gate electrode between the plurality of semiconductor patterns;
a backside conductive contact between the source/drain pattern and the power rail; and
a liner pattern on the pillar pattern,
wherein the liner pattern comprises:
a first portion that covers a top surface of a lower portion of the backside conductive contact; and
a second portion that extends from the first portion and along a sidewall of the lower portion of the backside conductive contact.
